(19) United States
(12) Patent Application Publication
(10) Pub. No.: US 2023/0394192 A1
(43) Pub. Date: Dec. 7, 2023

(54) SYSTEMS AND METHODS FOR A SYNTHETIC INFRASTRUCTURE MODEL FOR VULNERABILITY, FAILURE, AND FUTURE TRANSITION PLANNING

(71) Applicants: Mikhail Chester, Scottsdale, AZ (US); SK Nasir Ahmad, Knonxvill, TN (US); Nathan Johnson, Mesa, AZ (US); Ryan Hoff, Tucson, AZ (US)

(72) Inventors: Mikhail Chester, Scottsdale, AZ (US); SK Nasir Ahmad, Knonxvill, TN (US); Nathan Johnson, Mesa, AZ (US); Ryan Hoff, Tucson, AZ (US)

(73) Assignee: Arizona Board of Regents on Behalf of Arizona State University, Tempe, AZ (US)

(21) Appl. No.: 18/205,416

(22) Filed: Jun. 2, 2023

Related U.S. Application Data
(60) Provisional application No. 63/348,342, filed on Jun. 2, 2022.

(51) Int. Cl. G06F 30/18

(52) U.S. Cl. CPC G06F 30/18

(57) ABSTRACT

A computer-implemented SynF (Synthetic Infrastructure) model is designed to estimate the location and characteristics of urban water and power distribution networks, estimate how those networks are interconnected and connect to buildings and transportation systems, and assess how failures propagate within and across the systems. The model was designed using Phoenix metro area cities but has been extended to other cities.

### CROSS REFERENCE TO RELATED APPLICATIONS

This is a non-provisional application that claims benefit to U.S. Provisional Application Ser. No. 63/348,342, filed on Jun. 2, 2022, which is herein incorporated by reference in its entirety.

### GOVERNMENT SUPPORT

This invention was made with government support under Grant Nos. 1931324, 1934933, and 1444755 awarded by the National Science Foundation. The government has certain rights in the invention.

### FIELD

The present disclosure generally relates to infrastructure and urban planning systems, and in particular, to a system and associated methods for synthetic infrastructure modeling for vulnerability, failure, and future transition planning.

### BACKGROUND

Urban infrastructures are complex and vulnerable to cascading failures. A failure in one infrastructure has the potential to propagate to another, thereby causing significant disruption. Moreover, extreme events like hurricanes have shown their potential for disruption to large-scale infrastructure, most notably as power outages. Extreme event disruptions to people and the economy can be substantially greater than that of the physical damage to infrastructure. Understanding urban infrastructures, their relationships and propensity for cascading failures, is essential to preparing for future extreme events.

The dearth of available data on urban infrastructures is one of the main obstacles to better understanding the dynamics and interconnections among infrastructure at a fine scale. Often seemingly innocuous failures trigger a catastrophic hazard as the initial failure's magnitude increases over time as downstream assets go offline. Without precise information as to the nature of the cascade, tracking the root cause of such a failure is difficult. Fine-scale information and failure patterns are vital to prevent a similar future catastrophe. As such, it is necessary to know how each urban infrastructure is used and operates at a fine-scale to analyze the root cause of a catastrophic event. However, there is often limited to no fine-scale information on infrastructures due to weak historical records, security concerns, or limited willingness to share data.

It is with these observations in mind, among others, that various aspects of the present disclosure were conceived and developed.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a simplified diagram showing a system for interconnected infrastructure modeling, planning and fitness evaluation;

FIG. 2 is a simplified block diagram of an example process associated with the system described herein;

FIGS. 3A and 3B are respective graphical representations showing a synthesized water distribution network and a synthesized power distribution network applied to the Phoenix metro area; and

FIG. 4 is a simplified diagram showing an exemplary computing system for implementation of the system of FIG. 1.

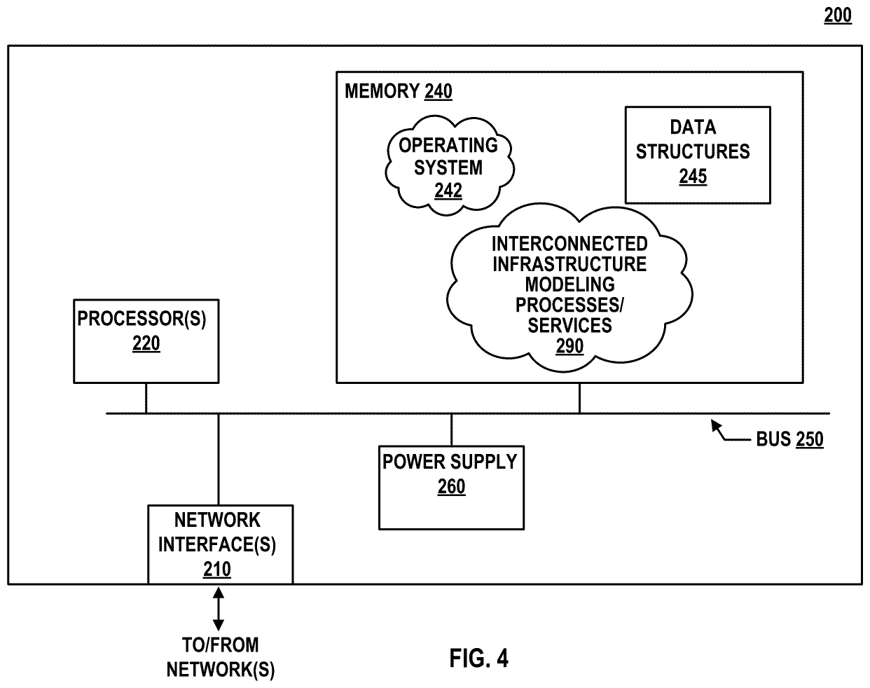

Corresponding reference characters indicate corresponding elements among the view of the drawings. The headings used in the figures do not limit the scope of the claims.

### DETAILED DESCRIPTION

Synthetic infrastructures are a promising solution to the lack of publicly available data on urban infrastructures. Synthetic infrastructures may allow us to better understand the dynamics of urban infrastructures and resilience strategies. Moreover, synthetic infrastructures are well positioned to support the modeling and understanding of interconnections among urban infrastructures. Synthetic infrastructure algorithms have been developed and used to illuminate the fine-scale dynamics (e.g., size of each water pipe) and use of urban infrastructures. For example, the SyNF (synthetic infrastructure) model was developed to synthesize a water distribution network (WDN) and provides critical information on water demand, pipe layout, and pipe diameter. Algorithms have been developed to generate a synthetic power distribution network (PDN) containing information on power demand, spatial layout, and distribution feeders. These models also show promise in their use in other simulation environments, e.g., EPANET and Open DSS. Although synthetic infrastructure algorithms provide useful information, their modeling capability has so far been limited to a single infrastructure. To better understand the criticality, adaptability, and vulnerability of networked systems, it is necessary to understand the interdependencies and interconnections among them.

It is necessary to view infrastructures as complex interconnected systems. Urban infrastructures are interdependent, the result of physical, cyber, spatial, logical, functional, policy, informational, and budgetary relationships. One can model interconnections among urban infrastructures in several ways: empirical approaches, agent-based approaches, system dynamics-based approaches, economic theory-based approaches, network-based approaches, and other approaches. Most of these approaches require significant input data, where data availability may be limited. A physical connection directly connects any component of one infrastructure to another. Moreover, all built infrastructures of an urban area share the same space; hence are connected geospatially. Therefore, a hazard in one infrastructure can spatially affect other infrastructures. For example, water from a broken water pipe can damage an underground power line or a transformer. Several institutions in the United States—including the National Infrastructure Protection Center (NIPC), the National Infrastructure Simulation and Analysis Center (NISAC), and the U.S. Department of Homeland Security (DHS)—are responsible for monitoring critical infrastructures. However, the criticality and sensitivity of data are protected under the US Protected Critical Infrastructure Information (PCII) categorization. And neighborhood (fine) scale data, where impacts often translate to impacts to people, require joining urban, regional, and national datasets. The development of synthetic infrastructure models offers significant promise to address these challenges.

The present disclosure provides a system 100 to synthesize models of an infrastructure and estimate the interdependencies of water, power, buildings, and roads for a city into a single platform. The system 100 then applies the model to scenarios of cascading failures to evaluate a fitness of the infrastructure and identify areas that need improvement. The system 100 uses synthetic algorithms to generate the water and power infrastructure and join with publicly available information for buildings and roads. After that, the system 100 models fundamental interdependencies among those infrastructures. SyNF was initially developed by the inventors of the present system 100 to describe the extent and characteristics of water distribution networks. As such, the system 100 builds on this existing platform by adding power, buildings, and roads. For development, geographically diverse cities including New York City, New York, the Phoenix, Arizona metro area, and Atlanta, Georgia were selected for case studies. These cities represent a diversity of infrastructure and configurations, as well as vulnerability to extreme events. First, the system 100 simulates a model of an urban infrastructure and develops city profiles. The system 100 then simulates cascading failure scenarios using the model to assess a fitness of the urban infrastructure.

### Model Overview

The modeling of interconnected urban infrastructures is based on key asset data and well-grounded shortest path and minimum spanning tree algorithms. After describing the synthesis approaches for water and power systems, the present disclosure discusses the collection of publicly available building and road information and the subsequent joining of the two systems to establish interdependent relationships. Methods for synthetically estimating networks are well-established but appear seriously limited in their applications. First, existing synthetic models appear mostly with power distribution networks at larger scales. Second, existing models do not capture multiple systems, their interdependencies, or the propensity of coupled systems to cascade to large failures. As such, the system 100 fills a particularly critical niche, the assessment of coupled infrastructure networks, their vulnerabilities, and opportunities for improving resilience.

Synthetic Water Distribution Network

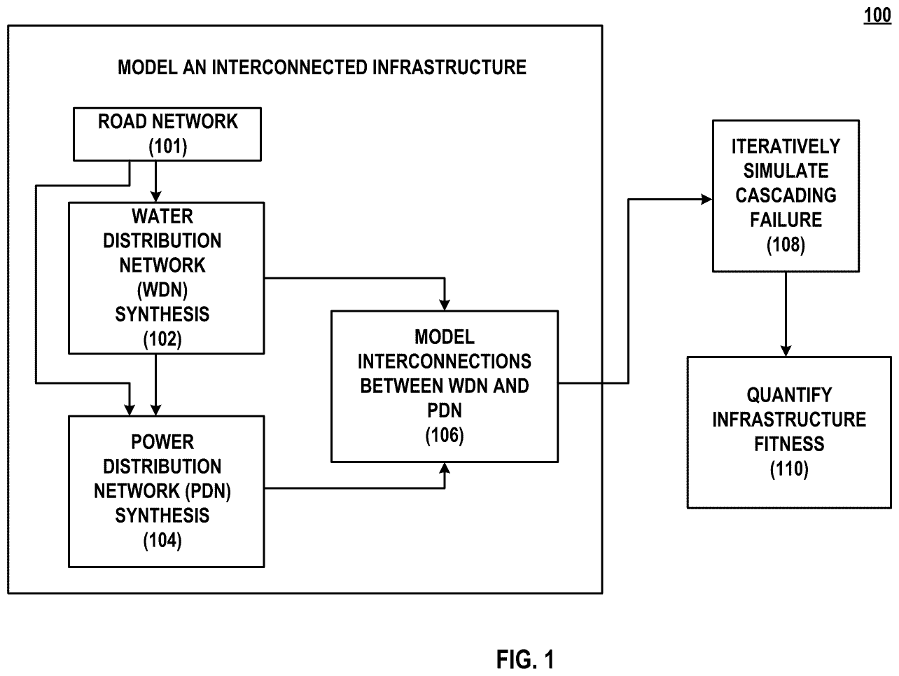

Referring to block 102 of FIG. 1, Water distribution network (WDN) synthesis for an infrastructure relies on the road network (block 101), water demand, and water sources (i.e., water treatment plant) to produce a spatially defined network with asset and operational characteristics. The synthesized WDN provides network topology, node elevation, pipe length, and pipe diameter. The network is based on the assumption that pipes follow roads, that pipes trunk from treatment plants, and that demand must be met.

The system 100 uses OpenStreetMap's road network to synthesize a water distribution network topology, assuming that underground water pipes largely align with road right-of-way. Referring to block 101, a road network is first converted to a graph in the model, where links are roads and nodes are intersections. Moreover, self-loops, parallel links, freeways, and expressways are removed to prune the graph. Each node represents demand from aggregated water use of nearby buildings. The system 100 uses SyNF to synthesizes a tree network representing a WDN by optimizing the total length of the WDN so that every node can receive water from its nearest possible source. The water main is the tree's trunk that collects water from the sources (e.g., water treatment plant) and distributes water to the pipes originating from the water main. Similarly, pipes that stem from the water main distribute water to the branches, and this process continues until each node is connected to form the network.

To estimate pipe capacity and flow, it is necessary to consider demand. An Integrated Urban Water Management (IUWM) model is used which considers census/demographic, land use and cover, and climate models to estimate the water demand at urban census block group scale. The estimated maximum monthly water demand for each block group is then equally distributed to the nodes within the neighborhood to get the nodal demand. To estimate pipe flow, peak hourly water demand is estimated using the Goodrich empirical equation. A continuity equation assuming a velocity (5 ft/s) to estimate pipe diameter.

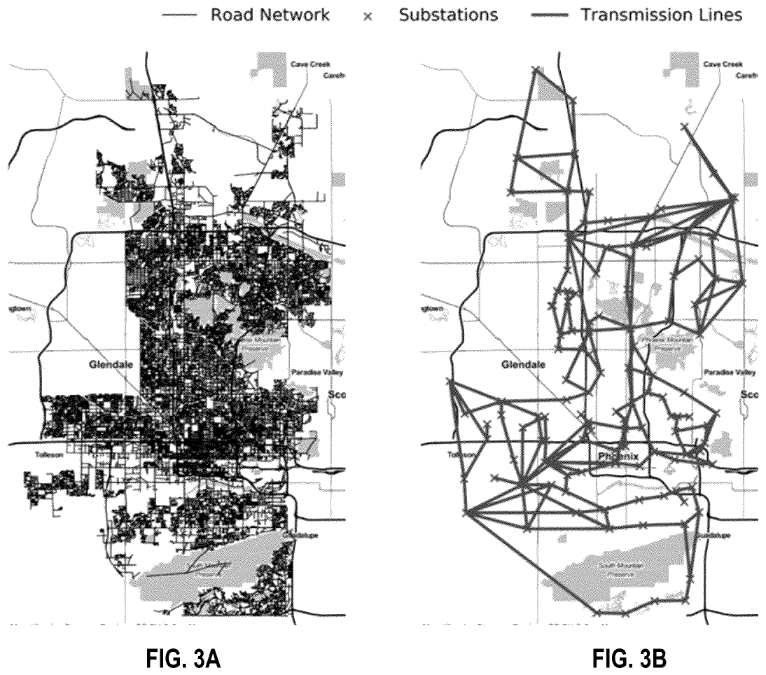

Finally, the system 100 uses the outputs from SyNF to model the probable locations of pumps, their capacity, and power requirement. First, the system 100 builds a WDN model in EPANET, the hallmark software for modeling water distribution systems. As the synthesized WDN follows a tree network, subparts of the network are also trees with a root node and many downstream nodes connected to the root through pipes. One objective of the system 100 is to minimize the number of nodes with a hydraulic pressure below a hydraulic pressure threshold value, which is in some embodiments 40 psi. Therefore, the system 100 first identifies those parts of the WDN whose root node exceeds that pressure and downstream nodes that are less. The link between the root node and its immediate downstream node is used as the location of the pump. The system 100 then uses an iterative approach, gradually increasing a pump's capacity to minimize the number of nodes with a hydraulic pressure below 40 psi and ensure that the network's maximum hydraulic pressure remains below 100 psi. Although all nodes of a city's WDN should have sufficient pressure, because of lack of information on secondary water sources (e.g., wells, reservoir tanks), one objective of the system 100 is to reduce the number of nodes below 40 psi to at least 10%. Moreover, in a real network, pumps are grouped in a pumping station to serve a more extensive area. The original SyNF, however, focuses on the number and probable location of pumps but does not combine them into a pumping station. FIG. 3A shows a synthesized water distribution network based on the Phoenix metro area.

Synthetic Power Distribution Network

Referring to block 104 of FIG. 1, Power infrastructure includes a power plant, transmission network, and distribution network (substations to users), where electricity is generated at a power plant and then transmitted to substations and finally distributed to buildings. The present disclosure focuses on the distribution network for this model. Following the water model, the system 100 starts by utilizing a road network from OpenStreetMap and the location of substations from the Homeland Infrastructure Foundation-Level Data (HIFLD). To simulate cascading failures, the services areas required a logical mode of interconnection, requiring the use of this real-world transmission and substation data to form a literal basis for interconnection and using the synthetic model to create the distribution network and service areas. In one embodiment, the system 100 imports 131 major substations into the model. Most of the substations (109) have a maximum output voltage of 69 kV; with 19 at 230 kV, one at 345 kV, and one at 500 kV.

To estimate the extent of distribution from substations, the system 100 first establishes substation service regions using Voronoi polygons. A Voronoi polygon is an estimated geometric area that consists of all the nearest points to a reference point in a plane. The system 100 uses the location of each substation as the reference point, and all the points within a polygon are nearest to that associated substation than other substations. Therefore, each Voronoi polygon has one substation that provides power to the entire polygon. Similar to the WDN, the system assumes that the power distribution network (PDN) follows the road network. Therefore, the road network within each Voronoi polygon is the PDN that gets power from the substation of that Voronoi region. The resulting synthetic PDN includes each substation's location and service area and the layout of the PDN. FIG. 3B shows the locations of the substations, transmission lines, distribution lines, and the service area (Voronoi region) of each substation of a synthesized PDN based on Phoenix metro area.

Interdependency Modeling

Referring to block 106 of FIG. 1, several approaches are used to model interdependencies between the four infrastructures. Note that this disclosure distinguishes between a dependency and an interdependency in how feedbacks (physical or otherwise) flow. A dependency is one where the feedback moves from a first infrastructure sub-system to a second infrastructure sub-system. If that second infrastructure sub-system then impacts the first—either directly or indirectly—then there is an interdependency. This section first discusses how the system 100 models interconnections between the two synthetic networks (i.e., WDN and PDN). Then, the present disclosure describes the modeling approach employed by the system 100 for connecting buildings to water and power.

Power is essential for each potable water supply system stage, and thus, a WDN is directly dependent on a PDN. Pumps, for example, need electricity to operate. As such, a failure in the PDN can cause a pump failure, and nodes downstream to that pump may be affected. To capture this dependency, the system 100 models the direct physical connection between water pumps and power distribution by connecting the respective nodes of both networks. As pumps are represented as links in EPANET, each pump (i.e., link) has a start and an end node and thus has two connections to the PDN. Using geospatial information from the synthesized WDN and PDN, the system 100 connects each pump's start and end nodes to nearby nodes of the PDN. Moreover, as the WDN and the PDN share the same urban space, when they are joined using their geolocation, an intrinsic spatial connection is established between them. This spatial connection allows the system 100 to assess geographic interdependencies. Therefore, outages of a particular asset (e.g., a pump) in one system can be assessed as larger-scale impacts in others (e.g., a large flooded area that disables transformers).

Cascading Failure Modeling

Referring to block 108 of FIG. 1, a primary objective of the system 100 is to set up a model of a feasible/real scenario of failure for the infrastructure and to elucidate conditions under which failure occurs at small and large scales, the particulars of the network that contribute to failure.

Components of a PDN and WDN are interconnected, and thus a failure of one component (e.g., a substation) can easily cascade within and across infrastructures. First, the system 100 develops a model to simulate the cascading failure within a PDN by simulating a substation failure. In particular, the system 100 connects substations through a transmission network, and when a substation fails, the connected substations to the failed substations are also prone to fail as they get a shock from the failure. One goal of the system 100 is to capture interdependent behavior among substations to ensure that some amount of realism is applied to the networks. In some embodiments, the system 100 uses the transmission line data from HIFLD to find interconnections among substations. Then, the system 100 assigns a random fitness factor ranging from 0.7 to 0.9 and a random disturbance factor ranging from 0.1 to 0.3 to each substation (block 110 of FIG. 1). The system 100 uses these random fitness and disturbance factors in equation 1 to simulate whether the connected substations will fail or not.

Fₜ+Fₜ₋₁*Dₜ₋₁ (1)

Where Fₜ₋₁ and Dₜ₋₁ are the fitness and disturbance factor of the failed substations at time (t−1) and Fₜ is the fitness factor of the substations connected to the failed substation at time (t−1). The system 100 applies Equation 1 (and/or a variation thereof) to each substation that is connected to a failed substation. If the outcome of equation 1 is greater than 1, then that substation is assumed to be failed too. This process continues until no failed substations are detected that are directly or indirectly connected to the initially failed (simulated) substation.

Rather than analyze only one cascading failure, the goal Monte Carlo simulations are appropriate methodologies for identifying the behavior of models across many simulations. To identify general behaviors, the system 100 models a long-term scenario of the infrastructure by using a Monte Carlo simulation with 10,000 iterations. To model the occurrence frequency, Poisson distributions are particularly useful for modeling discrete uncertain occurrences of events across time and space, such as with passenger arrivals or spontaneous machine failures that uses a single parameter lambda to vary the range and frequency of occurrences. To represent the discrete and also rare occurrence of substation outages, various lambda values can be tested such that for any single simulation—which represented a randomly selected time—the majority of initial outages were 0 substation failures with 1, 2, 3 etc., being increasingly rarer. Ultimately, using λ=0.4 yielded the most realistic scenario. As the number of failed substations is discrete, thus the Poisson distribution is used, a parametric discrete probability distribution. A test distribution of 10,000 simulations yields a 67% probability of no substation failure, 27% probability of 1 substation failure, 5% probability of 2 substations failure, and 0.7% probability of 3 substations failure as an initial outage.

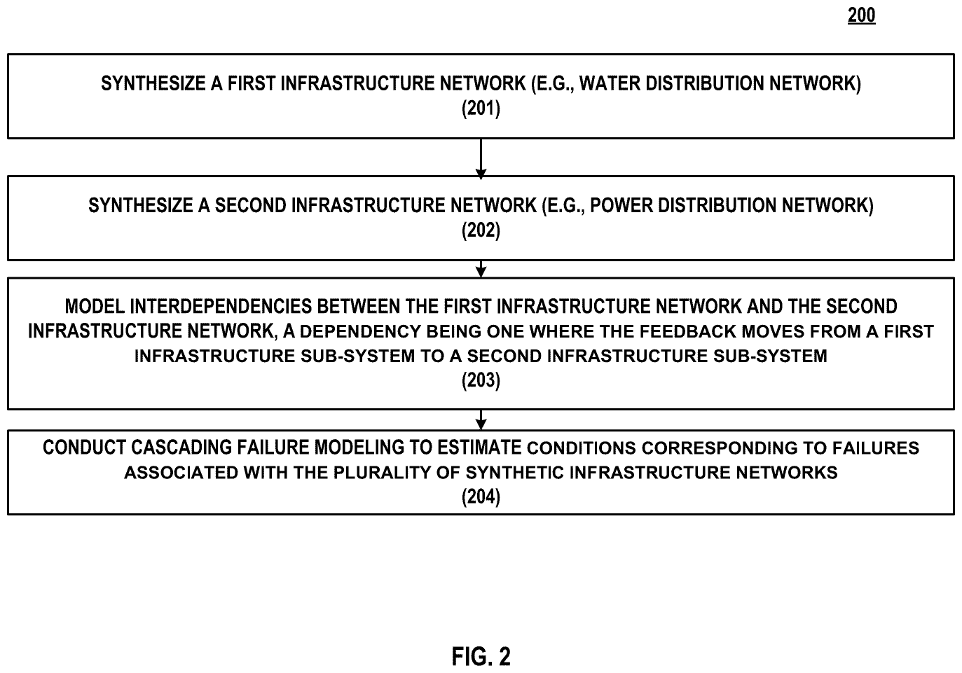

Blocks 201-204 of FIG. 2 provide a sample non-limiting method associated with the system 100 described herein.

### Computer-Implemented System

FIG. 3 is a schematic block diagram of an example device 200 that may be used with one or more embodiments described herein, e.g., as a component of system 100 shown in FIG. 1.

Device 200 comprises one or more network interfaces 210 (e.g., wired, wireless, PLC, etc.), at least one processor 220, and a memory 240 interconnected by a system bus 250, as well as a power supply 260 (e.g., battery, plug-in, etc.).

Network interface(s) 210 include the mechanical, electrical, and signaling circuitry for communicating data over the communication links coupled to a communication network. Network interfaces 210 are configured to transmit and/or receive data using a variety of different communication protocols. As illustrated, the box representing network interfaces 210 is shown for simplicity, and it is appreciated that such interfaces may represent different types of network connections such as wireless and wired (physical) connections. Network interfaces 210 are shown separately from power supply 260, however it is appreciated that the interfaces that support PLC protocols may communicate through power supply 260 and/or may be an integral component coupled to power supply 260.

Memory 240 includes a plurality of storage locations that are addressable by processor 220 and network interfaces 210 for storing software programs and data structures associated with the embodiments described herein. In some embodiments, device 200 may have limited memory or no memory (e.g., no memory for storage other than for programs/processes operating on the device and associated caches).

Processor 220 comprises hardware elements or logic adapted to execute the software programs (e.g., instructions) and manipulate data structures 245. An operating system 242, portions of which are typically resident in memory 240 and executed by the processor, functionally organizes device 200 by, inter alia, invoking operations in support of software processes and/or services executing on the device. These software processes and/or services may include interconnected infrastructure modeling processes/services 290 described herein. Note that while interconnected infrastructure modeling processes/services 290 is illustrated in centralized memory 240, alternative embodiments provide for the process to be operated within the network interfaces 210, such as a component of a MAC layer, and/or as part of a distributed computing network environment.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules or engines configured to operate in accordance with the techniques herein (e.g., according to the functionality of a similar process). In this context, the term module and engine may be interchangeable. In general, the term module or engine refers to model or an organization of interrelated software components/functions. Further, while the interconnected infrastructure modeling processes/services 290 is shown as a standalone process, those skilled in the art will appreciate that this process may be executed as a routine or module within other processes.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A system, comprising:
a processor in communication with a memory, the memory including instructions, which, when executed, cause the processor to:
synthesize a water network topology map of a model infrastructure that minimizes a number of nodes with a hydraulic pressure below a hydraulic threshold value, the water network topology map data being indicative of one or more intersections that consume water and one or more water pumps that distribute water;
synthesize a power network topology map of the model infrastructure based on the road network that includes data indicative of a plurality of power substations and power transmission data with respect to the road network;
model a set of interconnections between the water network topology map and the power network topology map, the set of interconnections being indicative of a physical dependency between each respective water pump in the water network topology map and each respective power substation in the power network topology map;
iteratively simulate a failure of one or more components of the model infrastructure resulting in effect data indicative of a simulated effect of the failure with respect to one or more nodes and/or edges of the water network topology map or the power network topology map; and
quantify a fitness of the model infrastructure including the simulation water network topology map and/or the power network topology map based on the effect data.

2. The system of claim 1, wherein a node of the set of nodes of the water network topology map is indicative of an intersection of a road network and includes data indicative of local water demand associated with the intersection.

3. The system of claim 2, wherein the data indicative of local water demand includes at least one of: a hydraulic pressure value and a water use rate.

4. The system of claim 1, where an edge of the set of edges of the water network topology map is a linkage between a first node indicative of a first intersection of a road network and a second node indicative of a second intersection of a road network, the edge including data indicative of water transfer by a water pump between the first intersection and the second intersection.

5. The system of claim 4, wherein the data indicative of water transfer includes at least one of: a pipe diameter and a flow rate.

6. The system of claim 1, wherein the memory includes instructions, which, when executed, further cause the processor to:
iteratively increase a number of edges of the water network topology map based on a simulated hydraulic pressure of each respective node of the water network topology map with respect to the hydraulic threshold value.

7. The system of claim 1, wherein a node of a set of nodes of the power network topology map is indicative of an intersection of a road network and includes data indicative of local power demand associated with the intersection.

8. The system of claim 7, wherein the data indicative of local power demand includes at least one of: a voltage value at the intersection and a power use rate.

9. The system of claim 1, wherein the memory includes instructions, which, when executed, further cause the processor to:
generate a plurality of Voroni polygons enclosing a plurality of reference points, where each reference point is indicative of a geometric position of a power substation and where each Voroni polygon is indicative of a geographic area covered by each respective reference point with respect to the road network

10. The system of claim 9, wherein each reference point is associated with a power output value.

11. The system of claim 1, where an edge of the set of edges of the power network topology map is a linkage between a first node indicative of a first intersection of a road network and a second node indicative of a second intersection of a road network, the edge including data indicative of power transfer between the first intersection and the second intersection.

12. The system of claim 1, wherein the memory includes instructions, which, when executed, further cause the processor to:
iteratively update one or more parameters of the power network topology map and/or a number of edges of the water topology map based on the fitness of the model infrastructure.

13. A method of modeling synthetic infrastructure, comprising:
generating a plurality of synthetic infrastructure networks, including:
synthesizing a water distribution network topology leveraging a clustering-based road network including converting the road network to a graph such that links include roads and nodes define intersections, and
synthesizing a power distribution network including a set of substations;
modeling interdependencies between the plurality of synthetic infrastructure networks; and
simulating cascading failure for the plurality of synthetic infrastructure networks to estimate conditions corresponding to failures associated with the plurality of synthetic infrastructure networks.

14. The method of claim 13, further comprising:
modeling a probable location of pumps including capacity and power requirements for the water distribution network.

15. The method of claim 13, further comprising:
establishing substation service regions for the power distribution network using Voronoi polygons including an estimated geometric area that consists of all the nearest points to a reference point in a plane.

16. The method of claim 15, wherein each Voronoi polygon has one substation that provides power to the entire polygon.

17. The method of claim 13, further comprising:
modeling a direct physical connection between water pumps and power distribution by connecting the respective nodes of both networks.

18. A non-transitory, computer-readable medium storing instructions that when executed by one or more processors cause the one or more processors to:
generate a plurality of synthetic infrastructure networks;
model interdependencies between the plurality of synthetic infrastructure networks; and
simulate cascading failure for the plurality of synthetic infrastructure networks to estimate conditions corresponding to failures associated with the plurality of synthetic infrastructure networks.

19. The non-transitory, computer-readable medium of claim 18 storing further instructions that when executed by the one or more processors cause the one or more processors to:
generate the plurality of synthetic infrastructure networks to include a water distribution network and a power distribution network.

20. The non-transitory, computer-readable medium of claim 19 storing further instructions that when executed by the one or more processors cause the one or more processors to:
simulate a substation failure associated with the power distribution network, the power distribution network including substations connected through a transmission network, wherein a failure of a given substation results in failures to connected substations.
